(19) United States
(12) Patent Application Publication
(10) Pub. No.: US 2026/0190554 A1
(43) Pub. Date: Jul. 2, 2026

(54) DISPLAY DEVICE

(71) Applicant: LG Display Co., Ltd., Seoul (KR)

(72) Inventors: Hyunjik BAE, Daegu (KR); SangMoo SONG, Seoul (KR)

(73) Assignee: LG Display Co., Ltd., Seoul (KR)

(21) Appl. No.: 19/380,438

(22) Filed: Nov. 5, 2025

(30) Foreign Application Priority Data
Dec. 30, 2024 (KR) 10-2024-0201243

(51) Int. Cl. H10H 20/855; H10H 20/831; H10H 29/37

(52) U.S. Cl. CPC H10H 20/855; H10H 20/831; H10H 29/37

(57) ABSTRACT

A display device includes a substrate and a plurality of organic pattern on the substrate and has a plurality of island patterns. A plurality of light emitting diodes is respectively disposed on the plurality of organic patterns. Each light emitting diode includes a first electrode, an emission layer on the first electrode, and a second electrode on the emission layer. The first electrode is disposed so as to enclose a top surface and a side surface of one of the plurality of organic patterns corresponding to the first electrode, thereby blocking paths through which out-gassing from the organic insulating film may diffuse toward the light emitting layer. Accordingly, pixel shrinkage and performance deterioration associated with out-gassing may be minimized.

### CROSS-REFERENCE TO RELATED APPLICATIONS

This application claims the priority of Korean Patent Application No. 10-2024-0201243 filed on Dec. 30, 2024, in the Korean Intellectual Property Office, the disclosure of which is incorporated herein by reference.

### BACKGROUND

### Technical Field

The present disclosure relates to a display device, and more particularly, to a display device in which pixel shrinkage due to out-gassing is minimized.

### Description of the Related Art

With the development of technologies in modern society, display devices are being used in various ways to provide information to users. Display devices are included in electronic signs that simply transmit visual information in one direction, as well as various electronic devices that require higher technology to check a user's input and provide information in response to the checked input.

For example, the display device may be included in a vehicle to provide various information to a driver and a passenger of the vehicle. However, the display device of the vehicle needs to display content appropriately so as not to interfere with the operation of the vehicle. For example, the display device needs to limit the display of content that may reduce concentration on driving while the vehicle is in operation.

### BRIEF SUMMARY

The present disclosure describes a display device structure that minimizes pixel shrinkage and performance degradation caused by outgassing from organic materials. Instead of using a continuous organic insulating film, the substrate includes a plurality of organic patterns, that is, island patterned organic insulating layers. This reduces the amount of organic material, thereby lowering outgassing while still planarizing the substrate surface for placement of the light emitting diodes. In addition, in some embodiments, the first electrode of each light emitting diode completely encloses the top and sides of each organic island pattern, effectively blocking the diffusion path of reactive gas molecules toward the emission layer.

In some embodiments, a plurality of inorganic patterns are respectively introduced between the plurality of organic patterns and the first electrode to provide further isolation. The display device also includes a dual light emitting diode structure within each pixel. One diode is paired with bar shaped optical members for wide viewing angles suitable for shared viewing, while the other diode is paired with hemispherical optical members for narrow viewing angles that provide privacy. The diodes can be selectively driven to switch between these modes, enabling dynamic control over viewing angles while maintaining performance.

Additional structural features include placement of contact holes outside the organic patterns to preserve the barrier against outgassing, as well as bank structures that define emission and non-emission areas while providing electrical and optical isolation. These features can help reduce degradation of the emission layers, may improve the operational lifetime of the display, and can contribute to more efficient operation by decreasing the likelihood of pixel defects.

For example, various embodiments of the present disclosure provide a display device that reduces out-gassing.

Various embodiments of the present disclosure is to provide a display device that blocks a path through which an out-gassing component diffuses to an emission layer.

Various embodiments of the present disclosure provide a display device in which pixel shrinkage due to out-gassing is minimized.

Various embodiments of the present disclosure provide a display device that has an an improved lifespan by minimizing a potential defect caused by pixel shrinkage.

Technical benefits of the present disclosure are not limited to the above-mentioned benefits, and other benefits, which are not mentioned above, can be clearly understood by those skilled in the art from the following descriptions.

According to an aspect of the present disclosure, a display device includes a substrate, a plurality of organic patterns disposed on the substrate, and a plurality of light emitting diodes which are respectively disposed on the plurality of organic patterns and each of which includes a first electrode, an emission layer disposed on the first electrode, and a second electrode disposed on the emission layer. The first electrode is disposed so as to enclose a top surface and a side surface of one of the plurality of organic patterns corresponding to the first electrode.

A display device according to an exemplary embodiment of the present disclosure includes a substrate with a pixel disposed thereon, the pixel including a plurality of organic patterns disposed to be spaced apart from each other, a first light emitting diode and a second light emitting diode disposed on the plurality of organic patterns, respectively, a first optical member disposed on the first light emitting diode and having a semi-cylindrical shape and a second optical member disposed on the second light emitting diode and having a semi-cylindrical shape. A first electrode of the first light emitting diode and a first electrode of the second light emitting diode are disposed to cover the plurality of organic patterns, respectively. Accordingly, pixel shrinkage due to out-gassing may be minimized.

Other detailed matters of the embodiments are included in the detailed description and the drawings.

According to the present disclosure, it is possible to reduce out-gassing by patterning the organic insulating film into a plurality of organic patterns.

According to the present disclosure, it is possible to block a path through which the out-gassing component diffuses from the organic pattern to the emission layer by shielding the organic pattern with the first electrode of the light emitting diode.

According to the present disclosure, it is possible to minimize pixel shrinkage due to out-gassing.

According to the present disclosure, it is possible to improve a lifespan of the display device by minimizing a potential defect caused by pixel shrinkage.

The effects according to the embodiments of the present specification are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is an exemplary view of a display device according to an exemplary embodiment of the present disclosure.

FIG. 2 is a functional block diagram of a display device according to an exemplary embodiment of the present disclosure.

FIG. 3 is an enlarged plan view of a pixel of a display device according to an exemplary embodiment of the present disclosure.

FIG. 4 is a cross-sectional view taken along line IV-IV′ of FIG. 3.

FIG. 5 is a cross-sectional view taken along line V-V′ in FIG. 3.

FIG. 6 is a cross-sectional view of a pixel of a display device according to another exemplary embodiment of the present disclosure.

FIG. 7 is a cross-sectional view of a pixel of a display device according to another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

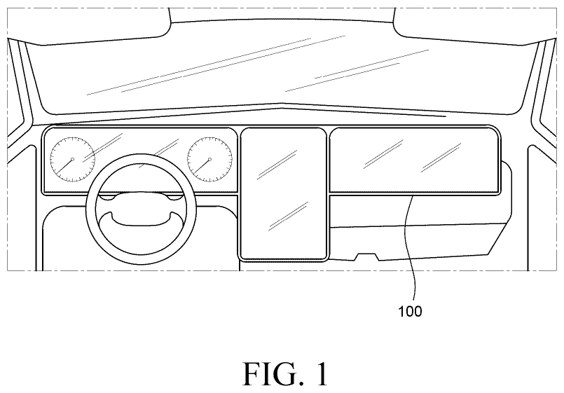

FIG. 1 is an exemplary view of a display device according to an exemplary embodiment of the present disclosure.

Referring to FIG. 1, a display device 100 may be disposed on at least a part of a dashboard of a vehicle. The dashboard of the vehicle may include a configuration disposed in front of front seats (e.g., driver's seat and front passenger seat) of the vehicle. For example, an input configuration for manipulating various functions (e.g., an air conditioner, an audio system, and a navigation system) inside the vehicle may be disposed on the dashboard of the vehicle.

The display device 100 may be disposed on the dashboard of the vehicle and operate as an input unit for manipulating at least some of various functions of the vehicle. The display device 100 may provide various information related to the vehicle, for example, driving information of the vehicle (for example, a current speed of the vehicle, a remaining fuel amount, and a driving distance), information on parts of the vehicle (for example, a damage degree of a vehicle tire), and the like.

The display device 100 may be disposed across the driver's seat and the front passenger's seat disposed in the front seats of the vehicle. The user of the display device 100 may include a driver of the vehicle and a passenger riding in the passenger seat. Both the driver and the passenger of the vehicle may use the display device 100. For example, the display device may provide various information to the driver and the passenger of the vehicle. However, the display device of the vehicle needs to display content appropriately so as not to interfere with the operation of the vehicle. For example, the display device needs to limit the display of content that may reduce concentration on driving while the vehicle is in operation, which will be described in detail hereinafter.

Only a part of the display device 100 illustrated in FIG. 1 may be illustrated. The display device 100 illustrated in FIG. 1 may represent a display panel among various configurations included in the display device 100. Specifically, for example, the display device 100 illustrated in FIG. 1 may represent at least a part of an active area and a non-active area of a display panel. Among the configurations of the display device 100, configurations other than those illustrated in FIG. 1 may be mounted inside (or at least a portion) of the vehicle.

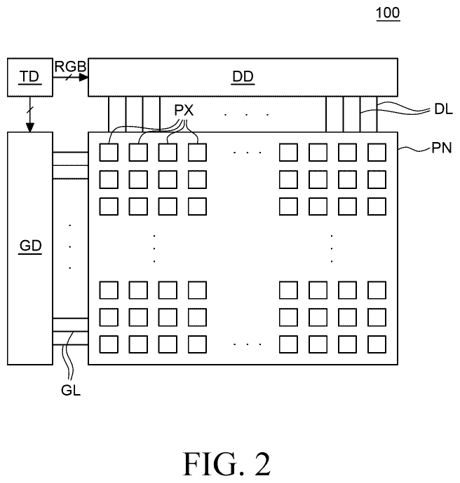

FIG. 2 is a functional block diagram of a display device according to an exemplary embodiment of the present disclosure.

An electroluminescent display device may be applied to a display device according to an exemplary embodiment of the present disclosure. The electroluminescent display device may be an organic light emitting diode display device, a quantum-dot light emitting diode display device, or an inorganic light emitting diode display device.

Referring to FIG. 2, the display device 100 may include a display panel PN, a data driving circuit DD, a gate driving circuit GD, and a timing controller TD.

The display panel PN may generate an image to be provided to the user. For example, the display panel PN may generate and display an image to be provided to the user through a plurality of pixels PX in which pixel circuits are disposed.

The data driving circuit DD, the gate driving circuit GD, and the timing controller TD may provide signals for the operation of each pixel PX through signal lines. For example, the signal lines for providing the signals for the operation of each pixel PX may include a plurality of data lines DL and a plurality of gate lines GL.

The plurality of data lines DL may include a plurality of lines arranged in a column direction and connected to pixels PX arranged in the column direction, and the plurality of gate lines GL may include a plurality of lines arranged in a row direction and connected to pixels PX arranged in the row direction.

In some cases, the display device 100 may further include a power unit. In this case, a signal for operating the pixel PX may be provided through a power line connecting the power unit and the display panel PN. In some embodiments, the power unit may provide power to the data driving circuit DD and the gate driving circuit GD. The data driving circuit DD and the gate driving circuit GD may be driven based on power provided from the power unit.

For example, the data driving circuit DD may apply a data signal to each pixel PX through a plurality of data lines DL, the gate driving circuit GD may apply a gate signal to each pixel PX through a plurality of gate lines GL, and the power unit may supply a power voltage to each pixel PX through a power voltage supply line.

The timing controller TD may control the data driving circuit DD and the gate driving circuit GD. For example, the timing controller TD may rearrange digital video data input from the outside to match the resolution of the display panel PN and supply the rearranged digital video data to the data driving circuit DD.

The data driving circuit DD may convert digital video data input from the timing controller TD into an analog data voltage based on a data control signal and supply the analog data voltage to the plurality of data lines DL.

The gate driving circuit GD may generate a scan signal and an emission signal based on a gate control signal. For example, the gate driving circuit GD may include a scan driver and an emission signal driver. The scan driver generates a scan signal in a row sequential manner to drive at least one scan line connected to each pixel row and may supply the scan signal to the scan lines. The emission signal driver generates an emission signal in a row sequential manner to drive at least one emission signal line connected to each pixel row to supply the emission signal to the emission signal lines.

According to the exemplary embodiment, the gate driving circuit GD may be disposed on the display panel PN in a gate-driver in panel (GIP) manner. For example, the gate driving circuit GD may be divided into a plurality of circuits and respectively disposed on at least two sides of the display panel PN.

The display panel PN may include an active area and a non-active area surrounding the active area.

The active area of the display panel PN may include multiple pixels PX disposed in the row direction and the column direction. For example, the plurality of pixels PX may be disposed in an area where the plurality of data lines DL and the plurality of gate lines GL intersect.

One pixel PX may include a plurality of sub-pixels emitting light of different colors. For example, one pixel PX may implement blue, red, and green colors using three sub-pixels. However, the present disclosure is not limited thereto, and in some cases, the pixel PX may further include a sub-pixel for further implementing a specific color, for example, white.

In the pixel PX, an area implementing blue may be referred to as a blue sub-pixel, an area implementing red may be referred to as a red sub-pixel, and an area implementing green may be referred to as a green sub-pixel.

Each of the plurality of pixels PX may include a first light emitting diode and a second light emitting diode which emit light of the same color.

Each of the plurality of pixels PX may include a first optical member that refracts light from the first light emitting diode in a specific direction and a second optical member that refracts light from the second light emitting diode in a specific direction in order to limit the display of content that may reduce concentration on driving while the vehicle is in operation. For example, each of the first optical member and the second optical member may be implemented as a lens, but the embodiment of the present specification is not limited thereto.

For example, the first optical member may be disposed in an optical area that provides light in a first range to form a first viewing angle, and the second optical member may be disposed in an optical area that provides light in a second range to form a second viewing angle. The first range may correspond to a range wider than the second range. Accordingly, the first optical member and the second optical member may limit the viewing angle of each of the plurality of pixels PX.

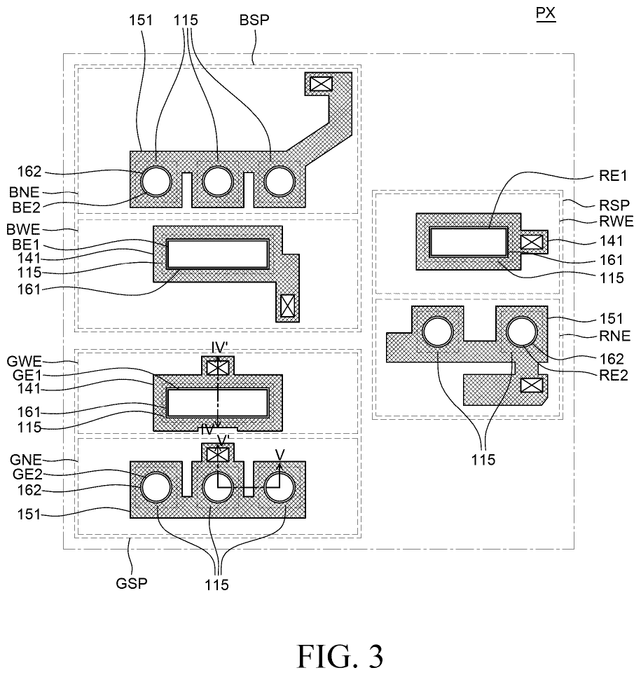

The first optical member and the second optical member will be described in detail below with reference to FIGS. 3 to 5.

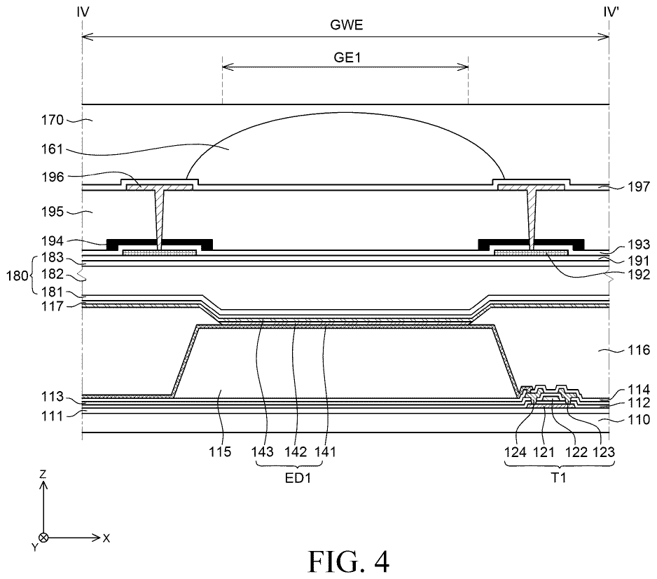

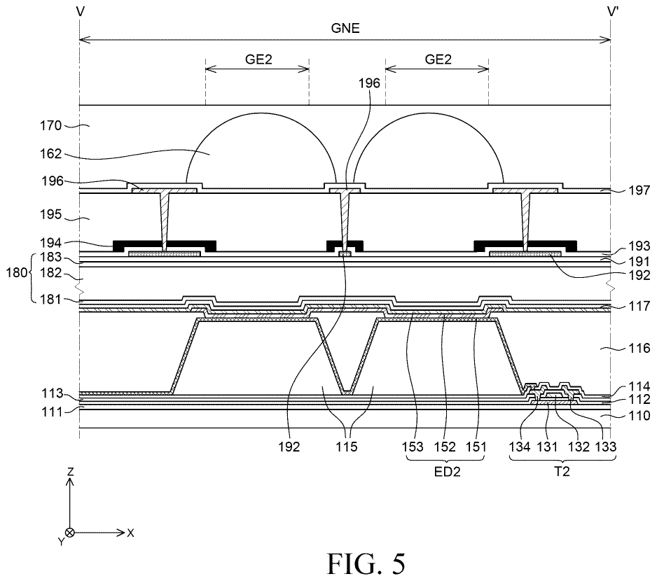

FIG. 3 is an enlarged plan view of a pixel of a display device according to an exemplary embodiment of the present disclosure. FIG. 4 is a cross-sectional view taken along line IV-IV′ of FIG. 3. FIG. 5 is a cross-sectional view taken along line V-V′ in FIG. 3.

Meanwhile, FIG. 3 illustrates a plane of the pixel PX when the pixel PX includes three sub-pixels, for example, a first sub-pixel RSP, a second sub-pixel GSP, and a third sub-pixel BSP.

In addition, FIG. 4 illustrates a pixel in which the first optical member 161 is disposed as an embodiment of the display device 100 cut along line IV-IV′ in FIG. 3, and FIG. 5 illustrates a pixel in which the second optical member 162 is disposed as an embodiment of the display device 100 cut along line V-V′ in FIG. 3.

Meanwhile, for convenience of description, FIGS. 4 and 5 illustrate only areas corresponding to the first optical area GWE and the second optical area GNE of the second sub pixel GSP, among the three sub pixels RSP, GSP, and BSP illustrated in FIG. 3, but the other sub pixels RSP and BSP may also have the same configuration. Particularly, a first optical area RWE and a second optical area RNE of the first sub pixel RSP, and a first optical area BWE and a second optical area BNE of the third sub pixel BSP have the same configuration as illustrated in FIGS. 4 and 5.

Meanwhile, for convenience of description, hereinafter, a horizontal direction on a plane is illustrated as a first direction X, and a vertical direction on a plane is illustrated as a second direction Y. Further, a normal direction of a plane defined by the first direction X and the second direction Y, for example, a thickness direction of the display device 100 may be defined as a third direction Z.

Referring to FIG. 3, the pixel PX may include a plurality of sub pixels RSP, GSP, and BSP representing different colors. For example, the pixel PX may include a first sub pixel RSP configured to implement red, a second sub pixel GSP configured to implement green, and a third sub pixel BSP configured to implement blue. According to the exemplary embodiment, the first sub pixel RSP may be referred to as a red sub pixel, the second sub pixel GSP may be referred to as a green sub pixel, and the third sub pixel BSP may be referred to as a blue sub pixel. A pixel circuit may be disposed in each of the plurality of sub pixels RSP, GSP, and BSP included in the pixel PX.

Each of the plurality of sub pixels RSP, GSP, and BSP may include first optical areas RWE, GWE, and BWE and second optical areas RNE, GNE, and BNE that provide different viewing angles.

The first optical areas RWE, GWE, and BWE of the sub pixels RSP, GSP, and BSP may operate individually from the second optical areas RNE, GNE, and BNE of the corresponding pixel PX. For example, each sub pixel RSP, GSP, BSP may include a first light emitting diode ED1 disposed in the first optical areas RWE, GWE, and BWE of the corresponding sub pixels RSP, GSP, and BSP, and a second light emitting diode ED2 disposed in the second optical areas RNE, GNE, and BNE of the corresponding sub pixels RSP, GSP, and BSP.

In one pixel PX, the first light emitting diode ED1 and the second light emitting diode ED2 may be disposed in the first optical areas RWE, GWE, and BWE and the second optical areas RNE, GNE, and BNE of the plurality of sub pixels RSP, GSP, and BSP, respectively.

For example, in one pixel PX, a first light emitting diode ED1 disposed in the first optical area RWE of the first sub pixel RSP, a second light emitting diode ED2 disposed in the second optical area RNE of the first sub pixel RSP, a first light emitting diode ED1 disposed in the first optical area GWE of the second sub pixel RSP, a second light emitting diode ED2 disposed in the second optical area GNE of the second sub pixel GSP, a first light emitting diode ED1 disposed in the first optical area BWE of the third sub pixel BSP, and a second light emitting diode ED2 disposed in the second optical area BNE of the third sub pixel BSP may be disposed.

Referring to FIG. 3, a plurality of organic patterns 115 may be disposed so as to overlap the first emission areas RE1, GE1, and BE1 of the first light emitting diode ED1 and the second emission areas RE2, GE2, and BE2 of the second light emitting diode ED2. FIG. 4 schematically shows the first emission area GE1 of the first light emitting diode ED1 of the second sub pixel GSP. FIG. 5 schematically shows the second emission area GE2 of the second light emitting diode ED2 of the second sub pixel GSP. The first emission area RE1 of the first light emitting diode ED1 of the first sub pixel RSP and the second emission area RE2 of the second light emitting diode ED2 of the first sub pixel RSP, and the first emission area BE1 of the first light emitting diode ED1 of the third sub pixel BSP and the second emission area BE2 of the second light emitting diode ED2 of the third sub pixel BSP may have the same configuration as shown in FIGS. 4 and 5. Each of the plurality of organic patterns 115 may be disposed below the first light emitting diode ED1 and the second light emitting diode ED2 to planarize an upper portion of the substrate 110 on which the first light emitting diode ED1 and the second light emitting diode ED2 are to be disposed. More details related to the plurality of organic patterns 115 will be described in detail with reference to FIGS. 4 and 5 to be described below.

At least one first optical member 161 which is disposed so as to overlap the first emission areas RE1, GE1, and BE1 of the first light emitting diode ED1 may be disposed in the first optical areas RWE, GWE, and BWE of the sub pixels RSP, GSP, and BSP. At least one second optical member 162 which is disposed so as to overlap the second emission areas RE2, GE2, and BE2 of the second light emitting diode ED2 may be disposed in the second optical areas RNE, GNE, and BNE of the sub pixels RSP, GSP, and BSP. In this case, the first optical areas RWE, GWE, and BWE may have a first viewing angle, and the second optical areas RNE, GNE, and BNE may have a second viewing angle smaller than the first viewing angle.

Referring to FIGS. 4 and 5 together, a display device 100 according to an exemplary embodiment of the present disclosure may include a substrate 110, a buffer layer 111, a gate insulating layer 112, an interlayer insulating layer 113, a passivation layer 114, an organic pattern 115, a bank 116, a capping layer 117, a first transistor T1, a second transistor T2, a first light emitting diode ED1, a second light emitting diode ED2, an encapsulation member 180, a touch buffer layer 191, a touch bridge electrode 192, a first touch insulating layer 193, a black matrix 194, a second touch insulating layer 195, a touch electrode 196, a third touch insulating layer 197, a first optical member 161, a second optical member 162, and an optical protective film 170.

The plurality of pixels PX may be disposed on the substrate 110. The substrate 110 may include an insulating material. The substrate 110 may include a transparent material. For example, the substrate 110 may include glass or plastic.

A buffer layer 111 may be disposed on the substrate 110. The buffer layer 111 may include an insulating material. For example, the buffer layer 111 may include an inorganic insulating material such as silicon oxide (SiOx) and silicon nitride (SiNx). The buffer layer 111 may have a multilayer structure. For example, the buffer layer 111 may have a stacked structure of a layer made of silicon nitride (SiNx) and a layer made of silicon oxide (SiOx).

The buffer layer 111 may be positioned between the substrate 110 and a driving portion of each sub pixel RSP, GSP, BSP. The driving portion of each sub pixel may be a driving transistor and a switching transistor. The buffer layer 111 may prevent contamination due to the substrate 110 during a process of forming the driving portion. For example, a top surface of the substrate 110 toward the driving portion of each sub pixel RSP, GSP, BSP may be covered by the buffer layer 111. The driving portion of each sub pixel RSP, GSP, BSP may be located on the buffer layer 111.

The gate insulating layer 112 may be disposed on the buffer layer 111. The gate insulating layer 112 may include an insulating material. For example, the gate insulating layer 112 may include an inorganic insulating material such as silicon oxide (SiOx) and silicon nitride (SiNx). The gate insulating layer 112 may include a material having a high dielectric constant. For example, the gate insulating layer 112 may include a high-K material such as hafnium oxide (HfO). The gate insulating layer 112 may have a multilayer structure.

The gate insulating layer 112 may extend between a first semiconductor layer 121 and a first gate electrode 122 of the transistor T1, and between a second semiconductor layer 131 and a second gate electrode 132 of the second transistor T2. For example, the first gate electrodes 122 of the first transistor T1 and the second gate electrode 132 of the second transistor T2 may be insulated from the semiconductor layer 121 of the first transistor T1 and the second semiconductor 131 of the second transistor T2 by the gate insulating layer 112, respectively. The gate insulating layer 112 may cover the first and second semiconductor layers 121 and 131 of each sub pixel RSP, GSP, BSP. The first gate electrodes 122 of the first transistor T1 and the second gate electrode 132 of the second transistor T2 may be located on the gate insulating layer 112.

The interlayer insulating layer 113 may be disposed on the gate insulating layer 112. The interlayer insulating layer 113 may include an insulating material. For example, the interlayer insulating layer 113 may include an inorganic insulating material such as silicon oxide (SiOx) and silicon nitride (SiNx). The interlayer insulating layer 113 may extend between the first and second gate electrodes 122 and 132 and the first and second source electrodes 123 and 133 and between the first and second gate electrodes 122 and 132 and the first and second drain electrodes 124 and 134 of each of the transistors T1 and T2. For example, the first and second source electrodes 123 and 133 and the first and second drain electrodes 124 and 134 of the first transistor T1 and the second transistor T2 may be insulated from the first and second gate electrodes 122 and 132 by the interlayer insulating layer 113. The interlayer insulating layer 113 may cover the first and second gate electrodes 122 and 132 of the first transistor T1 and the second transistor T2. The first and second source electrodes 123 and 133 and the first and second drain electrodes 124 and 134 of each sub pixel RSP, GSP, BSP may be positioned on the interlayer insulating layer 113. The gate insulating layer 112 and the interlayer insulating layer 113 may expose a source region and a drain region of each of first and second the semiconductor layers 121 and 131 positioned in each of the subpixels RSP, GSP, and BSP.

The passivation layer 114 may be disposed on the interlayer insulating layer 113. The passivation layer 114 may include an insulating material. For example, the passivation layer 114 may include an inorganic insulating material such as silicon oxide (SiOx) and silicon nitride (SiNx).

The passivation layer 114 may prevent damage to the driving portion due to external moisture and impact. The passivation layer 114 may extend along surfaces of the first transistor T1 and the second transistor T2. The passivation layer 114 may be in contact with the interlayer insulating layer 113 outside the driving portion located in each sub pixel RSP, GSP, BSP.

A plurality of organic patterns 115 may be disposed on the passivation layer 114. The organic pattern 115 may include an organic insulating material. For example, the organic pattern 115 may be formed of polyimide resin, acrylic resin, or benzocyclobutene (BCB) resin, but is not limited thereto.

The organic pattern 115 may partially remove a step caused by a driving portion of each sub pixel RSP, GSP, BSP.

The plurality of organic patterns 115 may be formed of an island pattern. That is, a plurality of organic patterns 115 may be disposed to be spaced apart from each other. For example, each of the plurality of organic patterns 115 may be patterned to be spaced apart from each other so as to correspond to the emission area. Therefore, each of the plurality of organic patterns 115 is disposed below the first light emitting diode ED1 and the second light emitting diode ED2 to planarize the upper portion of the substrate 110 on which the first light emitting diode ED1 and the second light emitting diode ED2 are to be disposed. Meanwhile, since the plurality of organic patterns 115 is formed by patterning an organic insulating film, out-gassing occurring in the organic pattern 115 may be relatively small compared to the case where the organic insulating film is disposed on the entire surface of the substrate 110.

The first transistor T1 and the second transistor T2 may be disposed on the substrate 110. The first transistor T1 may be electrically connected to the driving transistor and a first lower electrode 141 of the first light emitting diode ED1. The second transistor T2 may be electrically connected to the driving transistor and a second lower electrode 151 of the second light emitting diode ED2.

The first transistor T1 may include a first semiconductor layer 121, a first gate electrode 122, a first source electrode 123, and a first drain electrode 124. The first transistor T1 may have the same structure as the switching transistor and the driving transistor.

For example, the first semiconductor layer 121 may be positioned between the buffer layer 111 and the gate insulating layer 112, and the first gate electrode 122 may be positioned between the gate insulating layer 112 and the interlayer insulating layer 113. The first source electrode 123 and the first drain electrode 124 may be positioned between the interlayer insulating layer 113 and the passivation layer 114. The first gate electrode 122 may overlap the channel region of the first semiconductor layer 121. The first source electrode 123 may be electrically connected to a source region of the first semiconductor layer 121. The first drain electrode 124 may be electrically connected to a drain region of the first semiconductor layer 121.

The second transistor T2 may include a second semiconductor layer 131, a second gate electrode 132, a second source electrode 133, and a second drain electrode 134. For example, the second semiconductor layer 131 may be positioned on the same layer as the first semiconductor layer 121, the second gate electrode 132 may be positioned on the same layer as the first gate electrode 122, and the second source electrode 133 and the second drain electrode 134 may be positioned on the same layer as the first source electrode 123 and the first drain electrode 124.

The first light emitting diode ED1 and the second light emitting diode ED2 of each sub pixel RSP, GSP, BSP may be disposed on each of the plurality of organic patterns 115 of the corresponding sub pixel RSP, GSP, BSP.

The first light emitting diode ED1 may emit light representing a specific color. For example, the first light emitting diode ED1 may include a first lower electrode 141, a first emission layer 142, and a first upper electrode 143 sequentially stacked on the substrate 110.

The first lower electrode 141 may include a conductive material. The first lower electrode 141 may include a material having high reflectivity. For example, the first lower electrode 141 may include a metal such as aluminum (Al) and silver (Ag). The first lower electrode 141 may have a multilayer structure. For example, the first lower electrode 141 may have a structure in which a reflective electrode layer made of metal is positioned between transparent electrode layers made of a transparent conductive material such as Indium Tin Oxide (ITO) and Indium Zinc Oxide (IZO).

The first lower electrode 141 may be disposed to completely cover the organic pattern 115, thereby blocking a path through which the out-gassing component generated from the organic pattern 115 propagates to the first emission layer 142. For example, the first lower electrode 141 may be disposed along the shape of the organic pattern 115. Accordingly, the first lower electrode 141 is disposed to surround the upper surface and the side surface of the organic pattern 115 to shield the organic pattern 115.

Meanwhile, the first lower electrode 141 may be connected to the first transistor T1 through a contact hole of a layer other than the organic pattern 115. In other words, the contact hole connecting the first lower electrode 141 and the first drain electrode 124 may not be formed in the organic pattern 115. For example, the first lower electrode 141 may be disposed to extend on the passivation layer 114. Accordingly, the first lower electrode 141 may be electrically connected to the first drain electrode 124 of the first transistor T1 through a contact hole penetrating the passivation layer 114. Therefore, the contact hole of the passivation layer 114 connecting the first lower electrode 141 and the first drain electrode 124 may not overlap the organic pattern 115, but is not limited thereto.

The first emission layer 142 may generate light having a luminance corresponding to a voltage difference between the first lower electrode 141 and the first upper electrode 143. For example, the first emission layer 142 may include an emission material layer (EML) including a light emitting material. The light emitting material may include an organic material, an inorganic material, or a hybrid material.

The first emission layer 142 may have a multilayer structure. For example, the first emission layer 142 may further include at least one of a hole injection layer (HIL), a hole transport layer (HTL), an electron transport layer (ETL), and an electron injection layer (EIL).

The first upper electrode 143 may include a conductive material. The first upper electrode 143 may include a material different from that of the first lower electrode 141. The transmittance of the first upper electrode 143 may be higher than that of the first lower electrode 141. For example, the first upper electrode 143 may be a transparent electrode made of a transparent conductive material such as Indium Tin Oxide (ITO) and Indium Zinc Oxide (IZO). Accordingly, in the display device 100 according to the exemplary embodiment of the present disclosure, light generated by the first emission layer 142 may be emitted through the first upper electrode 143.

The second light emitting diode ED2 may implement the same color as the first light emitting diode ED1 disposed in the same sub pixel RSP, GSP, BSP. For example, the second light emitting diode ED2 may include a second lower electrode 151, a second emission layer 152, and a second upper electrode 153 sequentially stacked on the substrate 110.

The second lower electrode 151 may correspond to the first lower electrode 141, the second emission layer 152 may correspond to the first emission layer 142, and the second upper electrode 153 may correspond to the first upper electrode 143. For example, the second lower electrode 151 may be formed for the second light emitting diode ED2 with the same structure as the first lower electrode 141.

In other words, like the first lower electrode 141 of the first light emitting diode ED1, the first lower electrode 151 of the second light emitting diode ED2 may also be disposed to completely cover the organic pattern 115. Accordingly, the first lower electrode 151 may block the path through which the out-gassing component generated from the organic pattern 115 propagates to the second emission layer 152. Specifically, the second lower electrode 151 may be disposed along the shape of the organic pattern 115. Accordingly, the second lower electrode 151 is disposed to surround the upper surface and the side surface of the organic pattern 115 to shield the organic pattern 115.

In addition, like the first lower electrode 141, the second lower electrode 151 may be connected to the second transistor T2 through a contact hole of a layer other than the organic pattern 115. In other words, the contact hole which connects the second lower electrode 151 and the second drain electrode 134 may not be formed in the organic pattern 115. For example, the second lower electrode 151 may be disposed to extend on the passivation layer 114. Accordingly, the second lower electrode 151 may be electrically connected to the second drain electrode 134 of the second transistor T2 through a contact hole penetrating the passivation layer 114. Therefore, the contact hole of the passivation layer 114 connecting the second lower electrode 151 and the second drain electrode 134 may not overlap the organic pattern 115, but is not limited thereto.

The second emission layer 152 and the second upper electrode 153 may also be formed for the second light emitting diode ED2 with the same structure as the first emission layer 142 and the first upper electrode 143. For example, the first light emitting diode ED1 and the second light emitting diode ED2 may be formed to have the same structure. However, it is not limited thereto and in some cases, at least some configurations of the first light emitting diode ED1 and the second light emitting diode ED2 may be formed differently.

In the embodiment, the second emission layer 152 may be spaced apart from the first emission layer 142. Accordingly, in the display device according to the exemplary embodiment of the present disclosure, light emission due to a leakage current may be prevented.

According to the exemplary embodiment of the present disclosure, in the display device, light may be generated only in one of the first emission layer 142 and the second emission layer 152 according to a user's selection or a predetermined condition. In other words, the first light emitting diode ED1 and the second light emitting diode ED2 may be selectively driven, but are not limited thereto.

The second lower electrode 151 of each sub pixel RSP, GSP, BSP may be spaced apart from the first lower electrode 141 of the corresponding sub pixel RSP, GSP, BSP. For example, a bank 116 may be disposed between the first lower electrode 141 and the second lower electrode 151 of each sub pixel RSP, GSP, BSP. The bank 116 may include an insulating material. For example, the bank 116 may include an organic insulating material. The bank 116 may be formed of polyimide resin, acrylic resin, or benzocyclobutene (BCB) resin, which are the same organic material as the organic pattern 115, but is not limited thereto. Alternatively, the bank 116 may be made of a material different from that of the organic pattern 115. For example, a black component having a high light absorption rate may be included and may be configured by a black bank, but is not limited thereto.

The bank 116 is disposed to fill between the plurality of organic patterns 115 to remove a step caused by the driving portion of each sub pixel RSP, GSP, BSP. Accordingly, at least a part of the bank 116 may be disposed on the passivation layer 114 exposed by the plurality of organic patterns 115. In other words, at least a portion of the bank 116 may contact the passivation layer 114, but is not limited thereto.

In this case, each of the first lower electrode 141 of the first light emitting diode ED1 and the second lower electrode 151 of the second light emitting diode ED2 is disposed to completely cover the organic pattern 115, so that the bank 116 may be disposed to be spaced apart from the organic pattern 115 with the first lower electrode 141 and the second lower electrode 151 interposed therebetween, but is not limited thereto.

The second lower electrode 151 of each sub pixel RSP, GSP, BSP may be insulated from the first lower electrode 141 of the corresponding sub pixel RSP, GSP, BSP by the bank 116. For example, the bank 116 may cover an edge of the first lower electrode 141 and an edge of the second lower electrode 151 located in each sub pixel RSP, GSP, BSP. The bank 116 may distinguish the first emission areas RE1, GE1, and BE1 of the first light emitting diode ED1 and the second emission areas RE2, GE2, and BE2 of the second light emitting diode ED2. For example, the first emission areas RE1, GE1, and BE1 of the first light emitting diode ED1 may be defined by an edge area of the first lower electrode 141 covered by the bank 116. The second emission areas RE2, GE2, and BE2 of the second light emitting diode ED2 may be defined by an edge area of the second lower electrode 151 covered by the bank 116. The bank 116 further defines a non-emission area surrounding the first emission area and the second emission area, but the present disclosure is not limited thereto.

In this case, referring to FIG. 3, the size of the first emission areas RE1, GE1, and BE1 of the first light emitting diode ED1 divided in each sub pixel RSP, GSP, and BSP may be larger than the size of the second emission areas RE2, GE2, and BE2 of the second light emitting diode ED2, but is not limited thereto. The first emission layer 142 and the first upper electrode 143 of the first light emitting diode ED1 located in each sub pixel RSP, GSP, BSP may be stacked on a partial area of the corresponding first lower electrode 141 exposed by the bank 116. Specifically, the first emission layer 142 and the first upper electrode 143 may be stacked on the bank 116 and a partial area of the corresponding first lower electrode 141 exposed by the bank 116. The second emission layer 152 and the second upper electrode 153 of the second light emitting diode ED2 positioned in each of the subpixels RSP, GSP, and BSP may be stacked on a partial area of the corresponding second lower electrode 151 exposed by the bank 116.

Specifically, the second emission layer 152 and the second upper electrode 153 may be stacked on the bank 116 and a partial area of the corresponding second lower electrode 151 exposed by the bank 116. The second upper electrode 153 of each sub pixel RSP, GSP, BSP may be electrically connected to the first upper electrode 143 of the corresponding sub pixel RSP, GSP, BSP. For example, a voltage applied to the second upper electrode 153 of the second light emitting diode ED2 located in each sub pixel RSP, GSP, BSP may be equal to a voltage applied to the first upper electrode 143 of the first light emitting diode ED1 located in the corresponding sub pixel RSP, GSP, BSP.

The second upper electrode 153 of each sub pixel RSP, GSP, BSP may include the same material as the first upper electrode 143 of the corresponding sub pixel RSP, GSP, BSP. For example, the second upper electrode 153 of each sub pixel RSP, GSP, BSP may be formed simultaneously with the first upper electrode 143 of the corresponding sub pixel RSP, GSP, BSP. The second upper electrode 153 of each sub pixel RSP, GSP, BSP may extend onto the bank 116 to be in direct contact with the first upper electrode 143 of the corresponding sub pixel RSP, GSP, BSP. Luminance of the first optical areas RWE, GWE, and BWE and luminance of the second optical areas RNE, GNE, and BNE located in each sub pixel RSP, GSP, BSP may be controlled by a driving current generated in the corresponding sub pixel RSP, GSP, BSP.

A capping layer 117 may be disposed on the first light emitting diode ED1 and the second light emitting diode ED2 of each sub pixel RSP, GSP, BSP. The capping layer 117 may prevent damage to the first and second light emitting diodes ED1 and ED2 due to external moisture and impact. For example, the capping layer 117 may be formed of an inorganic insulating material such as silicon oxide (SiOx) or silicon nitride (SiNx), but is not limited thereto and may be formed of an organic insulating material.

The encapsulation member 180 may be located on the capping layer 117. The encapsulation member 180 may prevent damage to the first and second light emitting diodes ED1, and ED2 due to external moisture and impact. The encapsulation member 180 may have a multilayer structure. For example, the encapsulation member 180 may include a first encapsulation layer 181, a second encapsulation layer 182, and a third encapsulation layer 183 sequentially stacked, but is not limited thereto.

The first encapsulation layer 181, the second encapsulation layer 182, and the third encapsulation layer 183 may include an insulating material. The second encapsulation layer 182 may include a material different from those of the first encapsulation layer 181 and the third encapsulation layer 183. For example, the first encapsulation layer 181 and the third encapsulation layer 183 are inorganic encapsulation layers including an inorganic insulating material, and the second encapsulation layer 182 may include an organic encapsulation layer including an organic insulating material. Accordingly, the first and second light emitting diodes ED1 and ED2 of the display device 100 may be more effectively prevented from being damaged by external moisture and impact.

The touch buffer layer 191 may be disposed on the encapsulation member 180. The touch buffer layer 191 may be disposed between the encapsulation member 180 and the touch bridge electrode 192 to insulate the touch bridge electrode 192. For example, the touch buffer layer 191 may include an insulating material. For example, the touch buffer layer 191 may be formed of an organic insulating material or an inorganic insulating material, but is not limited thereto.

The touch bridge electrode 192 may be disposed on the touch buffer layer 191. The touch bridge electrode 192 may electrically connect the touch electrodes 196 on the second touch insulating layer 195. For example, the touch bridge electrode 192 may include a metal material such as titanium (Ti), aluminum (Al), silver (Ag), copper (Cu), and a magnesium-silver alloy (Mg:Ag), but is not limited thereto.

Referring to FIGS. 4 and 5 together, a first touch insulating layer 193 may be disposed on the touch bridge electrode 192. The first touch insulating layer 193 may be disposed between the touch bridge electrode 192 and the black matrix 194 to insulate the touch bridge electrode 192.

The first touch insulating layer 193 may include an insulating material. For example, the first touch insulating layer 193 may include an organic insulating material or an inorganic insulating material, but is not limited thereto.

A black matrix 194 may be disposed on the first touch insulating layer 193. The black matrix 194 may be disposed between the plurality of sub pixels RSP, GSP, and BSP to reduce a color mixture of the plurality of sub pixels RSP, GSP, and BSP. Accordingly, the black matrix 194 may be disposed to overlap the bank 116.

A second touch insulating layer 195 may be disposed on the black matrix 194. The second touch insulating layer 195 may be disposed between the black matrix 194 and the touch electrode 196 to insulate the touch electrode 196.

The second touch insulating layer 195 may include an insulating material. For example, the second touch insulating layer 195 may include an organic insulating material or an inorganic insulating material, but is not limited thereto.

A plurality of touch electrodes 196 may be disposed on the second touch insulating layer 195. The plurality of touch electrodes 196 may be configured to sense an external touch input using a user's finger or a touch pen. The touch electrode 196 may include, for example, a metal material such as titanium (Ti), aluminum (Al), silver (Ag), copper (Cu), and a magnesium-silver alloy (Mg:Ag), but is not limited thereto.

A third touch insulating layer 197 may be disposed on the touch electrode 196. The third touch insulating layer 197 may be disposed between the touch electrode 196 and the first and second optical member 161, 162 to insulate the touch electrode 196.

The third touch insulating layer 197 may include an insulating material. For example, the third touch insulating layer 197 may include an organic insulating material or an inorganic insulating material, but is not limited thereto.

The first optical member 161 and the second optical member 162 may be disposed on the third touch insulating layer 197.

For example, each of the first optical member 161 and the second optical member 162 may be disposed to cover edges of the plurality of touch electrodes 196, but is not limited thereto and may be disposed not to overlap the plurality of touch electrodes 196.

The first optical member 161 may be disposed on the first light emitting diode ED1. Light generated by the first light emitting diode ED1 of each sub pixel RSP, GSP, BSP may be emitted through the first optical member 161 disposed in the first optical areas RWE, GWE, and BWE of the corresponding sub pixel RSP, GSP, BSP.

The first optical member 161 may have a shape in which light in at least one direction may not be restricted. For example, a planar shape of the first optical member 161 located in each sub pixel RSP, GSP, BSP may have a bar shape extending in the first direction X. For example, a 3D shape of the first optical member 161 may have a semi-cylindrical shape extending in the first direction X.

In this case, the traveling direction of the light emitted from the first optical areas RWE, GWE, and BWE of the sub pixels RSP, GSP, and BSP may not be limited to the first direction X. For example, the content (or images) provided through the first optical areas RWE, GWE, and BWE of the sub pixels RSP, GSP, and BSP may be shared with surrounding people adjacent to the user in the first direction X. Accordingly, the content provided by the light emitted through the first optical member 161 may be provided within a first viewing angle range, which is wider than a second viewing angle range of the content provided by light emitted through the second optical member 162. For example, the content provided by the light emitted through the first optical member 161 is wide field-of-view mode (share mode).

The second optical member 162 may be disposed on the second light emitting diode ED2. Light generated by the second light emitting diode ED2 of each sub pixel RSP, GSP, BSP may be emitted through the second optical member 162 disposed in the second optical areas RNE, GNE, and BNE of the corresponding sub pixel RSP, GSP, BSP. The second optical member 162 may limit the traveling direction of light passing through the second optical member 162 to the first direction X and/or the second direction Y. For example, a planar shape of the second optical member 162 located in each sub pixel RSP, GSP, BSP may have a circular shape. For example, a 3D shape of the second optical member 162 may have a semi-spherical shape. However, the present disclosure is not limited thereto, and the planar shape of the second optical member 162 positioned in each of the subpixels RSP, GSP, and BSP may have a polygonal shape.

In this case, a traveling direction of light emitted from the second optical areas RNE, GNE, and BNE of the sub pixels RSP, GSP, and BSP may be limited to the first direction X and/or the second direction Y. For example, the content (or images) provided by the second optical areas RNE, GNE, and BNE of the sub pixels RSP, GSP, and BSP may not be shared with people around the user. Accordingly, the content provided by the light emitted through the second optical member 162 may be provided within the second viewing angle range, which is narrower than the first viewing angle range of the content provided by the light emitted through the first optical member 161. For example, the content provided by the light emitted through the second optical member 162 may be provided in a narrow field of view mode (private mode).

The first emission areas RE1, GE1, and BE1 of each of the sub pixels RSP, GSP, and BSP may have a shape corresponding to the first optical member 161 of the corresponding sub pixels RSP, GSP, and BSP. For example, the planar shape of the first emission areas RE1, GE1, and BE1 of each sub pixel RSP, GSP, BSP may have a bar shape extending in the first direction X. The first optical member 161 may have a larger size than the first emission areas RE1, GE1, and BE1 of the corresponding sub pixels RSP, GSP, and BSP. Accordingly, the efficiency of light emitted from the first emission areas RE1, GE1, and BE1 of the sub pixels RSP, GSP, and BSP may be improved.

The second emission areas RE2, GE2, and BE2 of the sub pixels RSP, GSP, and BSP may have a shape corresponding to the second optical member 162 of the corresponding sub pixels RSP, GSP, and BSP. For example, a planar shape of the second emission areas RE2, GE2, and BE2 of the sub pixels RSP, GSP, and BSP may have a circular or polygonal shape. The second optical member 162 may have a larger size than the second emission areas RE2, GE2, and BE2 of the corresponding sub pixels RSP, GSP, and BSP. Accordingly, the efficiency of light emitted from the second emission areas RE2, GE2, and BE2 of the sub pixels RSP, GSP, and BSP may be improved.

Depending on the exemplary embodiment, the first optical areas RWE, GWE, and BWE of one sub pixel RSP, GSP, BSP may include one first emission area RE1, GE1, and BE1. Further, the second optical areas RNE, GNE, and BNE of one sub pixel RSP, GSP, and BSP may include a plurality of second emission areas RE2, GE2, and BE2.

Depending on the exemplary embodiment, one first optical member 161 may be disposed on the first optical areas RWE, GWE, and BWE of one sub pixel RSP, GSP, BSP. Further, a plurality of second optical members 162 may be disposed on the second optical areas RNE, GNE, and BNE of one sub pixel RSP, GSP, BSP.

Referring to FIG. 3, the number of second emission areas RE2, GE2, and BE2 may be different for each of the sub pixels RSP, GSP, BSP. For example, the number of second emission areas GE2 defined in the second optical area GNE of the second sub pixel GSP and the number of second emission areas BE2 defined in the second optical area BNE of the third sub pixel BSP may be larger than the number of second emission areas RE2 defined in the second optical area RNE of the first sub pixel RSP. In this case, the efficiency deviation of the second light emitting diodes ED2 positioned in the second optical areas RNE, GNE, and BNE may be compensated by the number of second emission areas RE2, GE2, and BE2 defined in the second optical areas RNE, GNE, and BNE of the sub pixels RSP, GSP, and BSP.

The optical member protective film 170 may be positioned on the first optical member 161 and the second optical member 162 of the sub pixels RSP, GSP, and BSP. The optical member protective film 170 may include an insulating material. For example, the optical member protective film 170 may include an organic insulating material. The refractive index of the optical member protective film 170 may be smaller than the refractive index of the first optical member 161 and the refractive index of the second optical member 162 located in each sub pixel RSP, GSP, BSP. Accordingly, in the display device 100 according to the exemplary embodiment of the present disclosure, light passing through the first optical member 161 and the second optical member 162 of each sub pixel RSP, GSP, BSP may not be reflected toward the substrate 110 due to a difference in refractive index from the optical member protection film 170.

Among various components of the display device, some components made of an organic material may cause out-gassing due to photolysis of the organic material when exposed to UV for a long time. For example, the organic insulating film disposed below the light emitting diode may be made of an organic insulating material such as polyimide or acrylic. In this case, the polyimide or acrylic resin may generate a partially negatively charged gas such as NMP (N-Methyl-2-Pyrrolone) or nuconitrile by UV. In this way, the negatively charged out-gassing component may react with a positively charged compound in the emission layer. For example, the gas compound may react with a positively charged compound constituting the hole injection layer of the emission layer. Therefore, when such an out-gassing component diffuses into the emission layer, the performance of the emission layer may deteriorate. In addition, a defect in which the emission layer is degraded or contracted may occur due to deterioration, thereby reducing the lifespan of the display device.

Accordingly, in the display device 100 according to the exemplary embodiment of the present disclosure, the organic insulating film may be patterned to form the plurality of organic patterns 115. Specifically, the organic insulating film may be patterned to form a plurality of island patterns overlapping the first light emitting diode ED1 and the second light emitting diode ED2. Accordingly, the plurality of organic patterns 115 planarizes the upper surface of the substrate 110 in the area in which the first light emitting diode ED1 and the second light emitting diode ED2 are disposed, but the amount of the organic material may be relatively reduced compared to the case in which the organic insulating film is disposed on the entire surface of the substrate 110. Accordingly, the amount of out-gassing component occurring in the organic pattern 115 may be minimized.

In addition, in the display device 100 according to the exemplary embodiment of the present disclosure, each of the first lower electrode 141 of the first light emitting diode ED1 and the second lower electrode 151 of the second light emitting diode ED2 may shield the organic pattern 115. Specifically, the first lower electrode 141 of the first light emitting diode ED1 and the second lower electrode 151 of the second light emitting diode ED2 may be disposed to surround the upper surface and the side surface of the organic pattern 115 and disposed to completely cover the organic pattern 115. Therefore, the path through which the out-gassing component generated in the organic pattern 115 diffuses to the first emission layer 142 of the first light emitting diode ED1 and the second emission layer 152 of the second light emitting diode ED2 may be blocked. Accordingly, it is possible to minimize a defect in which the performance of the first light emitting diode ED1 and the second light emitting diode ED2 is degraded or the first light emitting diode ED1 and the second light emitting diode ED2 are deteriorated due to the out-gassing component. Accordingly, the lifespan of the display device 100 may be improved.

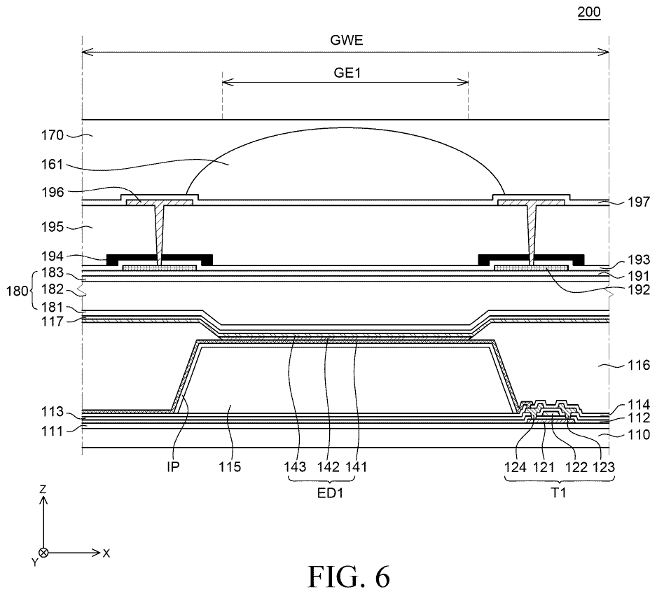

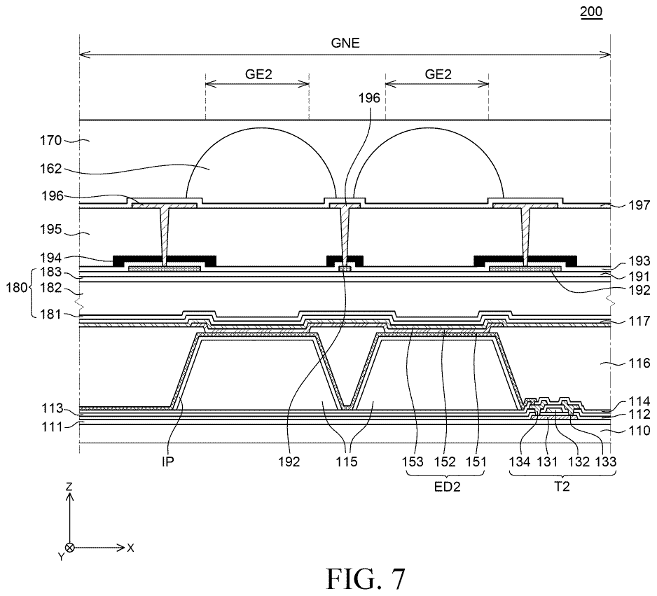

FIG. 6 is a cross-sectional view of a pixel of a display device according to another exemplary embodiment of the present disclosure. FIG. 7 is a cross-sectional view of a pixel of a display device according to another exemplary embodiment of the present disclosure. Specifically, FIG. 6 is a cross-sectional view corresponding to the same area as FIG. 3, and FIG. 7 is a cross-sectional view corresponding to the same area as FIG. 4. The only difference between a display device 200 of FIGS. 6 and 7 and the display device 100 of FIGS. 1 to 5 is the presence or absence of a plurality of inorganic patterns IP, but other components are substantially the same, so that a redundant description will be omitted.

Referring to FIGS. 6 and 7, a plurality of inorganic patterns IP may be disposed on the organic pattern 115. Specifically, a plurality of inorganic patterns IP may be disposed between the first light emitting diode ED1 and the organic pattern 115 and between the second light emitting diode ED2 and the organic pattern 115.

The plurality of inorganic patterns IP may be disposed to cover the plurality of organic patterns 115, respectively. For example, the inorganic pattern IP may be disposed along the shape of the organic pattern 115 so as to enclose upper and side surfaces of the organic pattern 115. Therefore, the organic pattern 115, the first lower electrode 141, and the second lower electrode 151 may be disposed to be spaced apart from each other with the inorganic pattern IP interposed therebetween. Accordingly, the out-gassing component generated in the organic pattern 115 may be prevented from being concentrated on the interface between the organic pattern 115 and the first lower electrode 141 and the interface between the organic pattern 115 and the second lower electrode 151. Therefore, deterioration of the first lower electrode 141 of the first light emitting diode ED1 and the second lower electrode 151 of the second light emitting diode ED2 may be minimized.

The plurality of inorganic patterns IP may be formed of an inorganic insulating material, for example, silicon oxide (SiOx) or silicon nitride (SiNx), but is not limited thereto.

In the display device 200 according to another exemplary embodiment of the present disclosure, the organic insulating film may be patterned to form a plurality of organic patterns 115. Specifically, the organic insulating film may be patterned to form a plurality of island patterns overlapping the first light emitting diode ED1 and the second light emitting diode ED2. Accordingly, the plurality of organic patterns 115 planarizes the upper surface of the substrate 110 in the area in which the first light emitting diode ED1 and the second light emitting diode ED2 are disposed, but the amount of the organic material may be relatively reduced compared to the case in which the organic insulating film is disposed on the entire surface of the substrate 110. Accordingly, the amount of out-gassing component occurring in the organic pattern 115 may be minimized.

In addition, in the display device 200 according to another exemplary embodiment of the present disclosure, each of the first lower electrode 141 of the first light emitting diode ED1 and the second lower electrode 151 of the second light emitting diode ED2 may shield the organic pattern 115. Specifically, the first lower electrode 141 of the first light emitting diode ED1 and the second lower electrode 151 of the second light emitting diode ED2 may be disposed to surround the upper surface and the side surface of the organic pattern 115 and disposed to completely cover the organic pattern 115. Therefore, the path through which the out-gassing component generated in the organic pattern 115 diffuses to the first emission layer 142 of the first light emitting diode ED1 and the second emission layer 152 of the second light emitting diode ED2 may be blocked. Accordingly, it is possible to minimize a defect in which the performance of the first light emitting diode ED1 and the second light emitting diode ED2 is degraded or the first light emitting diode ED1 and the second light emitting diode ED2 are deteriorated due to the out-gassing component. Accordingly, the lifespan of the display device 200 may be improved.

Specifically, in the display device 200 according to another exemplary embodiment of the present disclosure, the inorganic pattern IP may be additionally disposed between the first light emitting diode ED1 and the organic pattern 115 and between the second light emitting diode ED2 and the organic pattern 115. The inorganic pattern IP may be disposed to cover the organic pattern 115, such that the organic pattern 115 may be disposed to be spaced apart from the first lower electrode 141 of the first light emitting diode ED1 and the second lower electrode 151 of the second light emitting diode ED2. Therefore, the out-gassing component generated in the organic pattern 115 is prevented from being concentrated on the interface between the organic pattern 115 and the first lower electrode 141 and the interface between the organic pattern 115 and the second lower electrode 151. Therefore, deterioration of the first lower electrode 141 of the first light emitting diode ED1 and the second lower electrode 151 of the second light emitting diode ED2 may be minimized.

The Exemplary Embodiment of the present disclosure can also be described as follows:

According to an aspect of the present disclosure, a display device includes a substrate, a plurality of organic patterns disposed on the substrate, and a plurality of light emitting diodes which are respectively disposed on the plurality of organic patterns and each of which includes a first electrode, an emission layer disposed on the first electrode, and a second electrode disposed on the emission layer. The first electrode is disposed so as to enclose a top surface and a side surface of one of the plurality of organic patterns corresponding to the first electrode.

The first electrode may be disposed to cover the organic pattern corresponding to the first electrode.

The first electrode may be disposed along the shape of the organic pattern corresponding to the first electrode.

The display device may further include a bank covering an edge of the first electrode and defining an emission area and a non-emission area surrounding the emission area. The organic pattern corresponding to the first electrode and the bank may be spaced apart from each other with the first electrode interposed therebetween.

The display device may further include a transistor disposed on the substrate and a passivation layer disposed on the transistor. The first electrode may be disposed to extend to an upper surface of the passivation layer and connected to the transistor through a contact hole of the passivation layer.

The contact hole of the passivation layer may be disposed so as not to overlap the organic pattern corresponding to the first electrode.

The display device may further include a bank covering an edge of the first electrode and defining an emission area and a non-emission area surrounding the emission area. At least a portion of the bank may be in contact with the passivation layer.

The display device may further include an inorganic pattern disposed between the organic pattern corresponding to the first electrode and the first electrode. The inorganic pattern may be disposed to surround the upper surface and the side surface of the organic pattern corresponding to the first electrode.

The inorganic pattern may be disposed to cover the organic pattern corresponding to the first electrode.

The first electrode and the organic pattern corresponding to the first electrode may be disposed to be spaced apart from each other with an inorganic pattern interposed therebetween.

The display device may further comprise a plurality of optical members disposed on the plurality of light emitting diodes. The plurality of optical members may overlap the plurality of organic patterns, respectively.

A planar shape of each of the plurality of optical members may have a bar shape, or a circular or polygonal shape.

According to another aspect of the present disclosure, a display device includes a substrate with a pixel disposed thereon, the pixel including a plurality of organic patterns disposed on the substrate and spaced apart from each other, a first light emitting diode and a second light emitting diode disposed on the plurality of organic patterns, respectively, a first optical member disposed on the first light emitting diode and having a semi-cylindrical shape and a second optical member disposed on the second light emitting diode and having a semi-cylindrical shape. A first electrode of the first light emitting diode and a first electrode of the second light emitting diode are disposed to cover the plurality of organic patterns, respectively.

The first electrode of the first light emitting diode and the first electrode of the second light emitting diode may be disposed to cover upper surfaces and side surfaces of the plurality of organic patterns.

The display device may further include a plurality of transistors disposed on the substrate and a passivation layer disposed on the plurality of transistors. The first electrode of the first light emitting diode and the first electrode of the second light emitting diode may be connected to the plurality of transistors through a plurality of contact holes of the passivation layer, respectively. The plurality of contact holes may not overlap the plurality of organic patterns.

The display device may further include a plurality of inorganic patterns which are disposed between the plurality of organic patterns and the first electrode of the first light emitting diode and the first electrode of the second light emitting diode and are disposed to be spaced apart from each other. Each of the plurality of inorganic patterns may be disposed to cover each of the plurality of organic patterns.

The first electrode of the first light emitting diode and the first electrode of the second light emitting diode and the plurality of organic patterns may be disposed to be spaced apart from each other with the plurality of inorganic patterns interposed therebetween.

The first light emitting diode and the second light emitting diode may be selectively driven.

The first light emitting diode and the second light emitting diode may emit light of the same color.

The first optical member may provide light within a first viewing angle range, and the second optical member may provide light within a second viewing angle range which is narrower than the first viewing angle range.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate;
a plurality of organic patterns disposed on the substrate and has a plurality of island patterns; and
a plurality of light emitting diodes which are respectively disposed on the plurality of organic patterns and each of which includes a first electrode, an emission layer disposed on the first electrode, and a second electrode disposed on the emission layer,
wherein the first electrode encloses a top surface and a side surface of the organic insulating film one of the plurality of organic patterns corresponding to the first electrode.

2. The display device according to claim 1, wherein the first electrode is disposed to cover the organic pattern corresponding to the first electrode.

3. The display device according to claim 1, wherein the first electrode is disposed along the shape of the organic patterns corresponding to the first electrode.

4. The display device according to claim 1, further comprising:
a bank covering an edge of the first electrode and defining an emission area and a non-emission area surrounding the emission area,
wherein the organic pattern corresponding to the first electrode and the bank are spaced apart from each other with the first electrode interposed therebetween.

5. The display device according to claim 1, further comprising:
a transistor disposed on the substrate; and
a passivation layer disposed on the transistor,
wherein the first electrode extends to an upper surface of the passivation layer and is connected to the transistor through a contact hole of the passivation layer.

6. The display device of claim 5, wherein the contact hole of the passivation layer is disposed so as not to overlap the organic pattern corresponding to the first electrode.

7. The display device according to claim 5, further comprising:
a bank covering an edge of the first electrode and defining an emission area and a non-emission area surrounding the emission area,
wherein at least a part of the bank is in contact with the passivation layer.

8. The display device according to claim 1, further comprising:
an inorganic pattern disposed between the organic pattern corresponding to the first electrode and the first electrode,
wherein the inorganic pattern is disposed so as to enclose a top surface and a side surface of the organic pattern corresponding to the first electrode.

9. The display device according to claim 8, wherein the inorganic pattern is disposed to cover the organic pattern corresponding to the first electrode.

10. The display device according to claim 8, wherein the first electrode and the organic pattern corresponding to the first electrode are disposed to be spaced apart from each other with the inorganic pattern interposed therebetween.

11. The display device according to claim 1, further comprising:
a plurality of optical members disposed on the plurality of light emitting diodes,
wherein the plurality of optical members overlaps the plurality of organic patterns, respectively.

12. The display device according to claim 11, wherein a planar shape of each of the plurality of optical members has a bar shape, or a circular or polygonal shape.

13. A display device comprising:
a substrate with a pixel disposed thereon, the pixel including:
a plurality of organic patterns disposed to be spaced apart from each other;
a first light emitting diode and a second light emitting diode disposed on the plurality of organic patterns, respectively;
a first optical member disposed on the first light emitting diode and having a semi-cylindrical shape; and
a second optical member disposed on the second light emitting diode and having a semi-spherical shape,
wherein a first electrode of the first light emitting diode and a first electrode of the second light emitting diode are disposed to cover the plurality of organic patterns, respectively.

14. The display device according to claim 13, wherein the first electrode of the first light emitting diode and the first electrode of the second light emitting diode are disposed to cover upper surfaces and side surfaces of the plurality of organic patterns.

15. The display device of claim 13, further comprising:
a plurality of transistors disposed on the substrate; and
a passivation layer disposed on the plurality of transistors,
wherein the first electrode of the first light emitting diode and the first electrode of the second light emitting diode are connected to the plurality of transistors through a plurality of contact holes extending through the passivation layer, respectively, wherein the plurality of contact holes do not overlap the plurality of organic patterns.

16. The display device according to claim 13, further comprising:
a plurality of inorganic patterns which are disposed between the plurality of organic patterns and the first electrode of the first light emitting diode and the first electrode of the second light emitting diode, and are disposed to be spaced apart from each other,
wherein each of the plurality of inorganic patterns is disposed to cover each of the plurality of organic patterns.

17. The display device of claim 16, wherein the first electrode of the first light emitting diode and the first electrode of the second light emitting diode and the plurality of organic patterns are disposed to be spaced apart from each other with the plurality of inorganic patterns interposed therebetween.

18. The display device of claim 13, wherein the first light emitting diode and the second light emitting diode are configured to be selectively driven.

19. The display device of claim 13, wherein the first light emitting diode and the second light emitting diode are configured to emit light of the same color.

20. The display device of claim 13, wherein the first optical member provides light within a first viewing angle range, and the second optical member provides light within a second viewing angle range which is narrower than the first viewing angle range.
